(19) United States
(12) Patent Application Publication
(10) Pub. No.: US 2025/0388511 A1
(43) Pub. Date: Dec. 25, 2025

(54) TRANSPARENT SUBSTRATE PROVIDED WITH A FUNCTIONAL STACK OF THIN LAYERS

(71) Applicant: SAINT-GOBAIN GLASS FRANCE, COURBEVOIE (FR)

(72) Inventors: Cécile DELBECQ, AUBERVILLIERS (FR); Denis GUIMARD, AUBERVILLIERS (FR); Anne LELARGE, AUBERVILLIERS (FR); Romain HIVET, AUBERVILLIERS (FR)

(21) Appl. No.: 18/729,797

(22) PCT Filed: Jan. 5, 2023
(86) PCT No.: PCT/EP2023/050188

§ 371 Date: Feb. 19, 2025

(30) Foreign Application Priority Data
Jan. 27, 2022 (FR) FR2200706

(51) Int. Cl. C03C 17/34; B32B 7/12; B32B 17/10

(52) U.S. Cl. CPC C03C 17/3435; B32B 7/12; B32B 17/10036; B32B 17/10211; B32B 17/10339; C03C 2217/219; C03C 2217/24; C03C 2217/281; C03C 2217/74; C03C 2218/156

(57) ABSTRACT

A transparent substrate provided on one of its main surfaces with a stack of thin layers, the stack of layers including the following layers starting from the substrate a first dielectric module of one or more thin layers; an absorbent layer of tungsten oxide; a second dielectric module of one or more thin layers; wherein the tungsten oxide includes at least one doping element selected from the chemical elements of group 1 according to the IUPAC nomenclature, the absorbent layer of tungsten oxide includes cesium as a doping element, and the molar ratio of cesium to tungsten is between 0.01 and 1.

### TECHNICAL FIELD

The invention relates to a transparent substrate provided with a stack of thin layers conferring “solar control” and radiofrequency transparency properties.

### TECHNICAL BACKGROUND

With the aim of reducing greenhouse effect phenomena, it is common practice to use “solar control” glazings in motor vehicles. A “solar control” glazing is a glazing having the property of limiting energy flow, in particular infrared (IR) radiation, passing through it from the outside to the inside without detriment to the light transmission in the visible spectrum.

With the growth of connected vehicles and the Internet of Things, motor vehicles are currently equipped with on-board telecommunication systems (Wi-Fi or Bluetooth transmitters, GPS chips, etc.) enabling wireless communications with the outside environment. These systems can also interact with personal telecommunication devices (cell phone, etc.) of the driver and/or passengers.

Thus, in addition to the “solar control” property, glazings for motor vehicles must have properties of transparency to radio electromagnetic waves, in particular radiofrequency waves, which are commonly used in on-board telecommunications devices.

“Solar control” glazings provided with stacks of thin layers comprising metallic functional layers are generally not suitable for such applications. Indeed, the functional metallic layers block radio electromagnetic waves, in particular radiofrequency waves. The radio signal transmitted or detected by these telecommunication devices is then weakened, and the quality of communications becomes poor. Telecommunications may sometimes be impossible.

By way of example, according to an article by Rodríguez et al., “Radio Propagation into Modern Buildings: Attenuation Measurements in the Range from 800 MHz to 18 GHZ,” 2014 IEEE 80th Vehicular Technology Conference (VTC2014-Fall), 2014, pp. 1-5, a glazing which comprises a stack of layers comprising metallic functional layers can cause more than 30 dB attenuation of telecommunication signals.

It is common to use “solar control” glazings provided with a stack of thin layers with no metallic functional layers when radiofrequency transparency properties are desired. Instead of functional metallic layers, functional layers that absorb infrared radiation are generally used. They may be based on oxides and/or nitrides.

JP H0812378 A [NISSAN MOTOR] Jan. 16, 1996 describes a functional “solar control” stack comprising a tungsten oxide layer arranged between two oxide-based dielectric layers. The stack makes it possible to reduce the surface electrical resistance and to increase the transparency to radio waves relative to the stacks comprising a metallic functional layer, in particular based on silver.

JP 2010180449 A [SUMITOMO METAL MINING CO [JP]] Aug. 19, 2010 describes a layer based on tungsten oxide deposited by sputtering using a tungsten oxide target comprising chemical elements selected from hydrogen, alkali metals, alkaline earth metals and rare earth metals. The layer has a “solar control” function by virtue of its high absorption of near-infrared radiation.

WO 2012/020189 A1 [SAINT GOBAIN [FR]] 02.16.2012 describes a stack of thin layers comprising a layer selectively absorbing infrared radiation with a wavelength of greater than 800 nm. The absorbent layer consists of a titanium oxide substituted with a doping element X selected from Nb or Ta.

### SUMMARY OF THE INVENTION

### Technical Problem

For current motor vehicles, a glazing must satisfy a triple requirement: low solar factor, high light transmission, and transparency to radiofrequencies. This triple requirement can also be expressed as a double requirement: high selectivity and transparency to radiofrequencies.

### Solution to the Technical Problem

A first aspect of the invention relates to a transparent substrate as described in claim 1, the dependent claims being advantageous embodiments.

A second aspect of the invention relates to a laminated glazing comprising a transparent substrate according to the first aspect of the invention.

A third aspect of the invention relates to a method for manufacturing a transparent substrate according to the first aspect of the invention.

### Advantages of the Invention

A notable advantage of the substrate according to the first aspect of the invention is a gain of up to more than 30% on solar selectivity.

A notable advantage of the glazing according to the second aspect of the invention is a gain of up to more than 10% on the selectivity while maintaining a sufficient light transmission level, approximately 70%.

### BRIEF DESCRIPTION OF THE DRAWINGS

FIG. 1 is a schematic depiction of a first embodiment of the first aspect of the invention.

FIG. 2 is a schematic depiction of a second embodiment of the first aspect of the invention.

FIG. 3 is a schematic depiction of a third embodiment of the first aspect of the invention.

FIG. 4 is a schematic depiction of a laminated glazing according to the second aspect of the invention.

FIG. 5 is a comparison of the optical transmission spectra between an example of a substrate according to the first aspect of the invention and three counterexamples.

FIG. 6 is a schematic depiction of the light transmission and of the direct solar transmittance for four substrate examples according to the first aspect of the invention and five counterexamples.

FIG. 7 is a schematic depiction of the light transmission and of the solar factor for four examples of glazing according to the second aspect of the invention and one counterexample.

FIG. 8 is an internal reflection and external reflection representation for four examples of laminated glazing according to the second aspect of the invention and four counterexamples.

### DETAILED DESCRIPTION OF EMBODIMENTS

The following definitions and conventions are used.

The term “above”, respectively “below”, describing the position of a layer or of an assembly of layers and defined in relation to the position of another layer or another assembly, means that said layer or said assembly of layers is closer to, respectively further from, the substrate.

These two terms, “above” and “below”, do not at all mean that the layer or the assembly of layers which they describe and the other layer or the other assembly with respect to which they are defined are in contact. They do not exclude the presence of other intermediate layers between these two layers. The expression “in contact” is explicitly used to indicate that no other layer is positioned between them.

Without any fuller information or qualifier, the term “thickness” used for a layer corresponds to the physical, real or geometric thickness, e, of said layer. It is expressed in nanometers.

The expression “dielectric module” denotes one or more layers in contact with one another forming an assembly of layers which is dielectric overall, that is to say that it does not have the functions of a functional metal layer. If the dielectric module comprises several layers, they may themselves be dielectric. The physical, real or geometric thickness, of a dielectric module of layers, corresponds to the sum of the physical, real or geometric thicknesses, of each of the layers which constitute it.

In the present description, the expressions “a layer of” or “a layer based on”, used to describe a material or a layer as to what it contains, are used equivalently. They mean that the mass fraction of the constituent that it comprises is at least 50%, in particular at least 70%, preferably at least 90%. In particular, the presence of minority or doping elements is not excluded.

The term “transparent” used to describe a substrate means that the substrate is preferably colorless, non-opaque and non-translucent in order to minimize the absorption of the light and thus retain a maximum light transmission in the visible electromagnetic spectrum.

“Light transmittance,” TL, is understood to mean the light transmittance, denoted TL, as defined and measured and/or calculated in the standard ISO 13837:2021.

“Direct solar transmittance”, TE, is understood to mean the direct solar transmittance as defined and calculated according to the standard ISO 13837:2021.

“Solar factor”, T_{TS} (or T_{TS}), is understood to mean the solar factor as defined according to the standard ISO 13837:2021. It is equal to the sum of the direct solar transmittance, TE, and of the secondary heat flux, qi.

“Solar selectivity”, SE, is understood to mean the ratio between the light transmission, TL, to the direct solar transmittance, TE.

“Selectivity”, s, is understood to mean the ratio of the light transmission, LT, to the solar factor T_{TS}.

In accordance with the nomenclature of IUPAC, group 1 of the chemical elements comprises hydrogen and alkaline elements, that is, lithium, sodium, potassium, rubidium, cesium and francium.

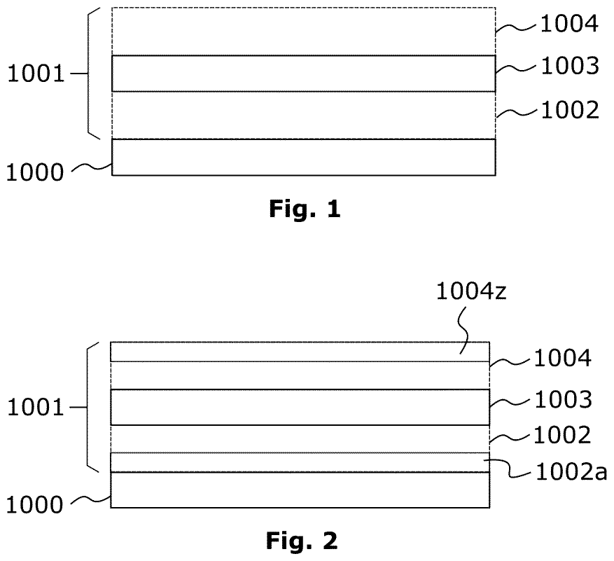

According to a first aspect of the invention, with reference to FIG. 1, a transparent substrate 1000 is provided, having on one of its main surfaces a stack 1001 of thin layers, said stack 1001 of layers consisting of the following layers starting from the substrate 1000:
a first dielectric module 1002 of one or more thin layers;
an absorbent layer 1003 of tungsten oxide;
a second dielectric module 1004 of one or more thin layers;

The tungsten oxide comprises at least one doping element selected from the chemical elements of group 1 according to the IUPAC nomenclature.

The absorbent layer 1003 of tungsten oxide is a layer that absorbs infrared radiation, preferably absorbing infrared radiation whose wavelength is greater than 780 nm.

Surprisingly, an absorbent layer 1003 of tungsten oxide comprising a doping element chosen from the elements of group 1 according to the nomenclature of the IUPAC encapsulated between two dielectric modules makes it possible to increase selectivity.

The stack 1001 of the transparent substrate 1000 according to the first aspect of the invention does not comprise any functional metallic layers. The absence of metallic layers makes it possible to ensure transparency to radio electromagnetic waves, in particular radiofrequency waves.

According to certain particular embodiments, the absorbent layer 1003 of tungsten oxide may comprise the doping element X or the doping elements X1, X2, . . . in proportions such that the molar ratio, X/W of said element to tungsten, W, or the sum of the molar ratios of each element to tungsten (X1+X2+ . . . )/W is between 0.01 and 1, preferably between 0.01 and 0.6, or even between 0.02 and 0.3.

It was observed that these values of molar ratio can make it possible to obtain optimal selectivity values while making it possible to limit the amount of doping elements used, and therefore to generate a saving on the exploitation of mineral resources for the doping elements, as well as a reduction in manufacturing costs.

According to certain embodiments, the absorbent layer 1003 of tungsten oxide may comprise at least one doping element selected from hydrogen, lithium, sodium, potassium and cesium.

Among the elements of group 1, these particular elements can make it possible to obtain advantageous selectivity values, that is higher values.

According to particularly preferred embodiments, the absorbent layer 1003 of tungsten oxide may comprise cesium as a doping element, and the molar ratio of cesium to tungsten is between 0.01 and 1, preferably between 0.01 and 0.4. These embodiments make it possible to obtain the best performance as to the increase in selectivity, the preservation of colors according to the specifications of the automobile industry, and cost savings.

According to certain embodiments, the thickness of the absorbent layer 1003 of tungsten oxide may be between 6 and 350 nm, preferably between 20 and 250 nm, or even between 40 and 200 nm.

The transparent substrate 1000 may preferably be planar. It may be of organic or inorganic nature, rigid or flexible. In particular, it may be a mineral glass, for example a soda-lime-silica glass.

Examples of organic substrates which can advantageously be used in the implementation of the invention may be polymer materials, such as polyethylenes, polyesters, polyacrylates, polycarbonates, polyurethanes or polyamides. These polymers can be fluoropolymers.

Examples of inorganic substrates which can advantageously be employed in the invention may be sheets of inorganic glass or glass-ceramic. The glass may preferably be a glass of soda-lime-silica, borosilicate, aluminosilicate or else alumino-borosilicate type. According to a preferred embodiment of the invention, the transparent substrate 1000 is a sheet of soda-lime-silica mineral glass.

According to certain embodiments, the first dielectric module 1002 and/or the second dielectric module 1004 may comprise one or more layers based on nitride and/or oxide, preferably based on zinc and tin oxide, zinc oxide, titanium oxide, zirconium oxide, aluminum nitride, silicon and zirconium nitride or silicon nitride optionally doped with aluminum, zirconium and/or boron.

According to certain preferred embodiments, with reference to FIG. 2, the first layer 1002a of the first dielectric module 1002 and the last layer 1004z of the second dielectric mode 1004 may be nitride-based layers, preferably based on aluminum nitride, silicon and zirconium nitride or silicon nitride optionally doped with aluminum, zirconium and/or boron.

When the first layer 1002a of the first dielectric module 1002 and the last layer 1004z of the second dielectric mode 1004 are nitride-based, they make it possible to encapsulate the absorbent layer based on tungsten oxide.

This encapsulation allows a double protection of the absorbent layer 1003 based on tungsten oxide. On the one hand, it prevents any contamination by elements capable of diffusing into the stack 1001 from the substrate 1000, such as in particular alkali metal or oxygen ions in the case of a mineral glass substrate. On the other hand, it makes it possible to limit, in particular during an annealing heat treatment step, the diffusion of oxygen into the stack 1001 toward the absorbent layer 1003 based on tungsten oxide from the atmosphere and/or the substrate.

By virtue of the encapsulation, the chemical composition and the degree of oxidation of the absorbent layer 1003 of tungsten oxide vary little over time, or if they vary, this variation is favorable for the selectivity. On the other hand, when the stack is subjected to an annealing heat treatment, the encapsulation ensures a correct level of selectivity. In use, the substrate 1000 according to the first aspect of the invention is more durable, in particular its performance is preserved over the long term.

The first dielectric module 1002, the second dielectric module 1004 and, more generally, the stack 1001 may comprise additional thin layers. In particular, these additional layers may have chemical compositions making it possible to confer particular optical properties to the substrate 1000, for example in terms of colors or filtering of certain wavelengths of the electromagnetic spectrum. They may also confer certain mechanical and/or chemical properties, such as resistance to abrasion, delamination and/or chemical attack. These layers are generally based on oxides or oxynitrides of metals or metal alloys.

5 Depending on their composition and their arrangement in the stack, these additional layers can be sources of contamination of the absorbent layer 1003 based on tungsten oxide. These sources of contamination may be a diffusion of certain metal or dopant ions or else an oxygen diffusion. They may take place during the deposition of the additional layers, during optional heat treatment of the stack, or else in use.

Such contaminations can alter the absorbent layer based on tungsten oxide and are detrimental to the performance of the substrate according to the first aspect of the invention.

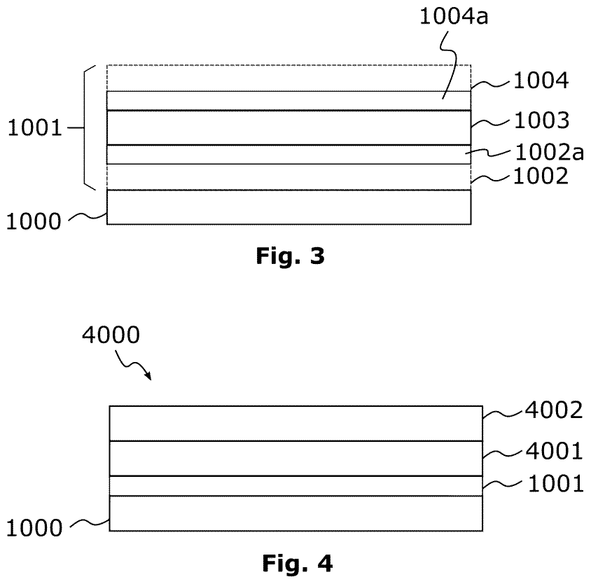

Thus, according to certain particular embodiments, with reference to FIG. 3, the last layer 1002z of the first dielectric module 1002 located under and in contact with the absorbent layer 1003 based on tungsten oxide and the first layer 1004a of the second dielectric module 1004 located on and in contact with the absorbent layer 1003 based on tungsten oxide are based on nitride, preferably based on aluminum nitride, on silicon and zirconium nitride or silicon nitride optionally doped with aluminum, zirconium and/or boron.

The absorbent layer 1003 of tungsten oxide is encapsulated by the layers 1002z, 1004a of the dielectric modules 1002, 1004. This type of encapsulation makes it possible to use any type of additional layers capable of imparting optical, mechanical and/or chemical properties while preserving any contamination by these additional layers adjacent to the absorbent layer 1003 based on tungsten oxide. The performance of the substrate according to the first aspect of the invention is thus preserved in use.

According to certain particular embodiments, the first dielectric module 1002 and/or the second dielectric module 1004 may consist of nitride-based layers, preferably based on aluminum nitride, silicon and zirconium nitride or silicon nitride optionally doped with aluminum, zirconium and/or boron.

When the first dielectric module 1002 and/or the second dielectric module 1004 consist of nitride-based layers, that is, they comprise only nitride-based layers. The risk of alteration of the absorbent layer based on tungsten oxide by optional oxygen diffusion is then limited, or eliminated. The durability of the substrate according to the first aspect of the invention may then be maximal as to the desired “solar control” and radiofrequency transparency performance.

A second aspect of the invention, with reference to FIG. 4, relates to a laminated glazing comprising a transparent substrate according to the first aspect of the invention. The laminated glazing 4000 comprises a first transparent substrate 1000 according to any embodiments of the first aspect of the invention, a lamination interlayer 4001 and a second transparent substrate 4002, such that the first transparent substrate 1000 and the second transparent substrates 4002 are in adhesive contact with the lamination interlayer 4001 and the stack 4001 of thin layers of the first transparent substrate 1000 is in contact with the lamination interlayer 4001.

The lamination interlayer may consist of one or more layers of thermoplastic material. Examples of thermoplastic material are polyurethane, polycarbonate, polyvynylbutyral (PVB), polymethyl methacrylate (PMMA), ethylene vinyl acetate (EA) or an ionomer resin.

The lamination interlayer may be in the form of a multilayer film. It may also have particular functionalities such as, for example, acoustic or anti-UV properties.

Typically, the lamination interlayer comprises at least one PVB layer. Its thickness is between 50 μm and 4 mm. In general, it is less than 1 mm.

According to certain preferred embodiments, the laminated glazing, when used as a glazing of a motor vehicle, for example as windshield, is such that the substrate according to the first aspect of the invention is located inside the vehicle. In other words, the stack 1001 is placed on face 2 of the glazing from the substrate oriented toward the interior of the vehicle, the face 1 being the face oriented towards the interior, or on face 3 of the glazing from the substrate oriented toward the exterior of the vehicle, the face 1 being the face oriented toward the exterior.

According to certain embodiments, one of the two substrates 1000, 4002 may be a mineral glass tinted in the mass. The tinting or coloring in the mass of a mineral glass is known and abundantly described in the technical literature. The coloring may generally be obtained by adding coloring oxide in the glass chemical composition. Examples of coloring oxides may be iron Il oxide, copper oxide, chromium oxide, nickel oxide, gold oxide, manganese oxide, cobalt oxide, uranium oxide, neodymium oxide and erbium oxide. Mixtures of oxides such as copper and tin oxide, or ionic complexes, such as iron-sulfur or cadmium-sulfur complex, can also be used.

The methods for depositing thin layers on substrates, in particular glass substrates, are methods well known in industry. By way of example, the deposition of a stack of thin layers on a glass substrate is carried out by successive depositions of each thin layer of said stack by passing the glass substrate through a succession of deposition cells suitable for depositing a given thin layer.

The deposition cells can use deposition methods such as magnetic field assisted sputtering, ion beam assisted deposition (IBAD), evaporation, chemical vapor deposition (CVD), plasma enhanced chemical vapor deposition (PECVD), low pressure chemical vapor deposition (LPCVD), etc.

The magnetic field enhanced sputtering deposition method is particularly used. The conditions for deposition of layers are widely documented in the literature, for example in patent applications WO2012/093238 A1 and WO2017/00602 A1.

According to a third aspect of the invention, a method is provided for manufacturing a transparent substrate according to the first aspect of the invention, wherein the absorbent layer of tungsten oxide is deposited by a magnetron sputtering method using a tungsten oxide target doped using a chemical element chosen from the chemical elements of group 1 according to the IUPAC nomenclature.

The tungsten oxide target may in particular contain one or more doping elements in the proportions as described for the tungsten oxide layer doped in some embodiments of the first aspect of the invention.

The absorbent layer of tungsten oxide can be deposited by sputtering using the aforementioned target under a deposition atmosphere composed of 60 to 100% argon and 0 to 40% dioxygen, preferably 70 to 85% argon and 15 to 30% dioxygen.

The absorbent tungsten oxide layer may be deposited under a pressure between 1 to 15 mTorr, preferably 3 to 10 m Torr.

Preferably, the deposition can be carried out cold, that is to say at a temperature of less than 100° C., in particular between 20° C. and 60° C., for the substrate.

The deposition can also be carried out hot, in particular at a temperature between 100° C. and 400° C.

According to particular embodiments, the substrate 1000, after deposition of the stack 1001, can undergo an annealing heat treatment. The annealing temperature may be between 450° C. and 800° C., in particular between 550° C. and 750° C., or even between 600° C. and 700° C. The annealing time may be between 5 min and 30 min, in particular between 5 min and 20 min, or even between 5 min and 10 min.

The transparent substrate according to the first aspect of the invention and the laminated glazing according to the second aspect are particularly suitable for glazing applications for motor vehicles. They can also be adapted to certain glazing applications for a building, in particular as laminated glazings.

All the embodiments described, whether they relate to the first aspect or the second aspect of the invention, can be combined with one another without modification or particular adaptation. In the event that technical incompatibilities appear during the implementation of one of these combinations, it is within the scope of the person skilled in the art to be able to solve them by means of their knowledge without this requiring undue effort, in particular by implementing a research program.

### EXAMPLES

The features and advantages of the invention are shown by the non-limiting examples described hereinafter.

A first example Ex1 of substrate according to the first aspect of the invention and three counterexamples CEx1, CEx2 and CEx3 not in accordance with the invention are described in Table 1, which indicates the composition and the thickness of the various layers expressed in nanometers. The numbers in the first column correspond to the references of the figures.

In example Ex1 and the three counterexamples CE1, CE2 and CE3, the transparent substrate is a soda-lime-silica glass with a thickness of 4 mm sold under the trade name Planiclear®.

TABLE 1

| | | E1 | CE1 | CE2 | CE3 |
|---|---|---|---|---|---|
| 1004 | Si3N4x | 10 | — | — | 10 |
| 1003 | CWO | 100 | 100 | 100 | 100 |
| 1002 | Si3N4 | 10 | — | 10 | |
| 1000 | glass | 4 mm | 4 mm | 4 mm | 4 mm |

The absorbent layer of tungsten oxide (CWO) comprises the cesium doping element (Cs). The molar ratio of cesium to tungsten is about 0.05-0.1. The absorbent layer is deposited by magnetron sputtering using a target of tungsten oxide doped with cesium in an atmosphere comprising between 10% and 20% of dioxygen at a pressure of 4 mTorr.

The layer or layers of silicon nitride, Si3N4, are deposited using a target Si:Al 8 wt % at 5 ubar under an atmosphere devoid of dioxygen and under nitrogen flow at 14 sccm.

After deposition of the thin layers, the substrates were subjected to an annealing heat treatment at 650° C. in air for 10 min.

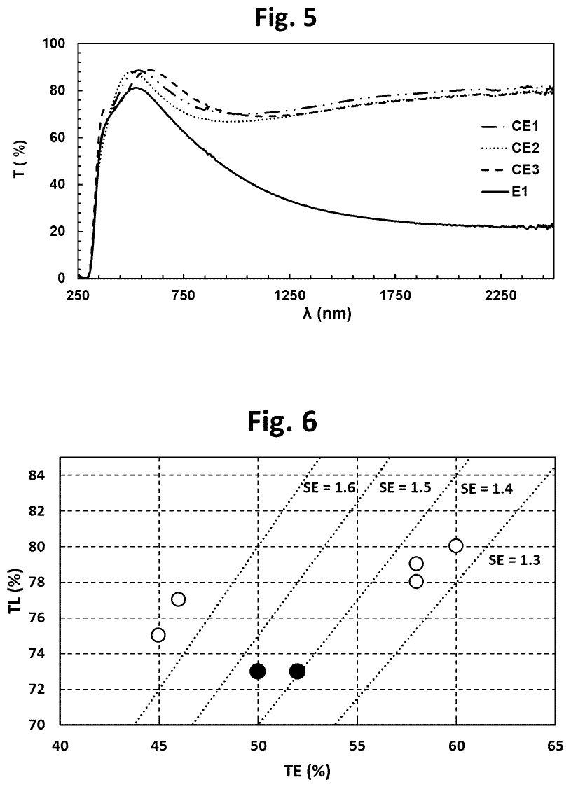

The optical transmission spectra of example E1 and of the three examples CE1, CE2 and CE3 were measured and/or calculated in accordance with standard ISO 13837:2021. They are shown in FIG. 5.

The three counterexamples CE1, CE2 and CE3 have a high light transmission both in the visible and the infrared. In other words, the layer based on tungsten oxide doped with cesium has little absorption in the infrared range. The three counterexamples have no “solar control” property.

On the contrary, example E1 of substrate according to the invention has a high light transmission in the visible range, and reduced in the infrared range. In other words, the layer based on tungsten oxide doped with cesium has a high absorption in the infrared range. Example E1 has a “solar control” property.

Two other examples E4 and E5 of substrates according to the first aspect of the invention are described in Table 2 which indicates the composition and thickness of the various layers expressed in nanometers. The numbers in the first column correspond to the references of the figures.

TABLE 1

| | | E2 | E3 | E4 | E5 | E6 | E7 |
|---|---|---|---|---|---|---|---|
| 1004 | Si3N4x | 47 | 47 | 5 | 30 | 31 | 5 |
| 1003 | CWO | 104 | 49 | 109 | 53 | 24 | 8 |
| 1002 | Si3N4 | 18 | 56 | 18 | 49 | 28 | 37 |
| 1000 | glass | 1.6 mm | 1.6 mm | 1.6 mm | 1.6 mm | 1.6 mm | 1.6 mm |

In examples E2, E3, E4, E5, E6 and E7, the transparent substrate is a soda-lime-silica glass of 1.6 mm sold under the trade name Planiclear®. The absorbent layer of tungsten oxide (CWO) comprises the cesium doping element (Cs). The molar ratio of cesium to tungsten is about 0.05-0.1.

The absorbent layer was deposited by magnetron sputtering using a tungsten oxide target doped with cesium in an atmosphere comprising 20% dioxygen at a pressure of 4 mTorr for examples E2, E4 and E6, and in atmosphere comprising 10% dioxygen at a pressure of 4 m Torr for E3, E5, and E7

The layer or layers of silicon nitride, Si3N4, are deposited using a target Si:Al 8 wt % at 5 ubar under an atmosphere devoid of dioxygen and under nitrogen flow at 14 sccm.

After deposition of the thin layers, the substrates were subjected to an annealing heat treatment at 650° C. in air for 10 min.

The light transmission, TL and the “direct solar transmittance”, TE, were measured and/or calculated according to standard ISO 13837:2021.

“Solar selectivity”, SE, defined as the ratio, TL/TE, of the light transmission TL to the direct solar transmittance TE, was also calculated. The results for Examples E4 and E5 are described in Table 4 and shown in FIG. 6.

For comparison purposes, Table 4 and FIG. 6 also group the light transmission, TL, solar transmittance, TE and solar selectivity values, SE, for counterexamples CE4, CE5, CE6, CE7, CE8 respectively corresponding to examples 1, 2, 3, 8 and 9 of the substrates described in application JP H0812378 A [NISSAN MOTOR] 01.16.1996. The characteristics of the counterexamples are given in Table 3. The numbers in the first column correspond to the references of the figures.

TABLE 3

| | CE4 | CE5 | CE6 | CE7 | CE8 |
|---|---|---|---|---|---|
| Example No. | 1 | 2 | 3 | 8 | 9 |
| JP H0812378 A | | | | | |
| 1004 | SiO2 | SiO2 | SiO2 | TiO2 | TiO2 |
| | 50 nm | 10 nm | 30 nm | 15 nm | 20 nm |
| 1003 | WO | SiWO | SiWO | SiWO | SiWO |
| | 80 nm | 90 nm | 90 nm | 100 nm | 25 nm |
| 1002 | SiO2 | SiO2 | SiO2 | TiO2 | TiO2 |
| | 100 nm | 10 nm | 20 nm | 15 nm | 25 nm |
| 1000 | glass | glass | glass | glass | glass |

For all the counterexamples CE4, CE5, CE6, CE7, CE8, the substrate is a transparent mineral glass. In the counterexample CE4, the absorbent layer is a tungsten oxide layer not comprising any dopant. In counterexamples CE5 to CE8, the absorbent layer is a tungsten oxide layer comprising silicon as a dopant with a Si:W ratio of 0.1:1 for counterexamples CE5 and CE6 and a Si:W ratio of 0.2:1 for counterexamples CE7 and CE8. The dielectric modules consist of a single layer of SiO2 for counterexamples CE4 to CE6, and a single layer of TiO2 for counterexamples CE7 to CE8.

TABLE 4

| | E4 | E5 | CE4 | CE5 | CE6 | CE7 | CE8 |
|---|---|---|---|---|---|---|---|
| TL (%) | 73 | 73 | 78 | 80 | 75 | 79 | 77 |
| TE (%) | 50 | 52 | 58 | 60 | 45 | 58 | 46 |
| SE | 1.47 | 1.39 | 1.34 | 1.33 | 1.67 | 1.36 | 1.67 |

The results of Table 4 and FIG. 6 show that examples E4 and E5 according to the first aspect of the invention have better solar selectivity, SE, compared to counterexamples CE4, CE5 and CE7 while preserving a light transmission of greater than 70%.

The comparison of counterexamples CE5 and CE6, on the one hand, and counterexamples CE7 and CE8, on the other hand, shows that their direct solar transmission, TE, varies greatly when the thicknesses of the thin layers, in particular those contained in dielectric modules, vary very little. The solar selectivity properties of the counterexamples are therefore very sensitive to small variations in the thicknesses of the layers.

Four laminated glazing examples EV1, EV2, EV3 and EV4 according to the second aspect of the invention were produced from the substrates of examples E2, E3, E6 and E7. A counterexample CEV1 of laminated glazing was also made from the substrate of example CE1. All these examples and counterexamples are described in Table 5. The numbers in the first column correspond to the references of the figures.

TABLE 5

| | EV1 | EV2 | EV3 | EV4 | CEV1 | CEV2 | CEV3 |
|---|---|---|---|---|---|---|---|
| 4002 | PLC 2.1 | PLC 2.1 | TSA3 + | TSA3 + | PLC 2.1 | TSA3 + | TSA5 + |
| | | | 2.1 | 2.1 | | 2.1 | 2.1 |
| 4001 | PVB | PVB | PVB | PVB | PVB | PVB | PVB |
| | 0.76 mm | 0.76 mm | 0.76 mm | 0.76 mm | 0.76 mm | 0.76 mm | 0.76 mm |
| 1000/1001 | E2 | E3 | E6 | E7 | CE1 | PLC | PLC |
| | | | | | | 1.6 | 1.6 |

counterexample CEV1, the lamination interlayer 4001 is a PVB interlayer 0.76 mm thick. The second substrate 4002 is a soda-lime-silica mineral glass with a thickness of 2.1 mm sold under the trade name Planiclear® (PLC 2.1) for examples EV1, EV2 and counterexample CEV1. For examples EV3 and EV4, the second substrates are respectively two soda-lime-silica mineral glasses tinted in the mass, 2.1 mm thick and sold under the name TSA3+, TSA5+ for examples EV3 and EV4.

Table 5 also describes two counterexamples CEV2 and CEV3 which do not comprise a stack of thin layers. These two counterexamples are reference examples corresponding to laminated glazings commonly used in the automotive field.

The light transmission, TL, the “direct solar transmittance”, TE, and the “solar factor”, T_{TS} (or T_{TS}) were measured and/or calculated according to ISO standard 13837:2021 for each example and counterexample.

The “selectivity”, s, defined as the ratio, TL/T_{TS}, of the light transmission, LT, to the solar factor T_{TS}, and the “solar selectivity”, SE, defined as the ratio, TL/TE, of the light transmission TL to the direct solar transmittance, TE, were calculated for each example and counterexample from the parameters measured and/or calculated previously.

For each example and counterexample, the colorimetric parameters a* and b* were measured and/or calculated in transmission (a*T, b*T) and in external reflection (a*Rext, b*Rext) in the L*a*b*CIE 1976 chromatic space according to standard ISO 11664-4:2019 with a D65 illuminant and a visual field of 2° or 10° for the reference observer. The characteristic a* is the chromatic position on a green-red axis (between −500 and 500), and b* the chromatic position on a blue-yellow axis (between −200 and 200).

All the measurement and/or calculation results are grouped in Table 6.

TABLE 6

| | EV1 | EV2 | EV3 | EV4 | CEV1 | CEV2 | CEV3 |
|---|---|---|---|---|---|---|---|
| TL | 70.9 | 69.7 | 69.7 | 70.1 | 83.8 | 78.6 | 73.2 |
| TE | 50.7 | 51.1 | 46.6 | 47.7 | 76.1 | 55.0 | 47.0 |
| SE | 1.40 | 1.36 | 1.50 | 1.47 | 1.10 | 1.43 | 1.56 |
| TTS | 61.7 | 61.8 | 59.1 | 59.9 | 79.7 | 65.3 | 59.6 |
| s | 1.15 | 1.13 | 1.18 | 1.17 | 1.05 | 1.20 | 1.23 |
| a*T | −2.9 | −3.9 | −5.5 | −5.5 | 0.9 | −5.1 | −6.7 |
| b*T | −6.1 | 1.9 | 0.9 | 3.6 | 4.8 | 2.3 | 3.9 |
| Rext | 10.5 | 8.9 | 11.8 | 11.6 | 13.3 | 7.2 | 6.8 |
| a*Rext | −9.4 | −5.4 | −5.1 | −4.5 | −8.2 | −1.9 | −2.3 |
| b*Rext | −5.3 | −4.8 | 0.9 | −2.8 | −3.9 | 0.3 | 0.7 |

Table 6 shows that the four examples EV1 to EV4 according to the second aspect of the invention make it possible to gain up to more than 35% on solar selectivity, SE, relative to the counterexample CEV1. This gain illustrates the synergistic effect of the combination of the absorbent layer based on tungsten oxide with the two adjacent dielectric modules, in particular when they comprise and/or consist of thin layers based on silicon nitride.

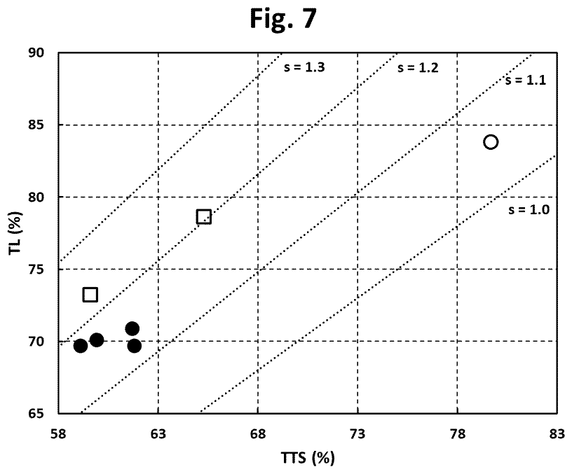

The light transmission, TL and solar factor, T_{TS} values are shown in FIG. 7 for examples EV1 to EV4 (solid circles), counterexample CEV1 (empty circle), and counterexamples CEV2 and CEV3 (empty squares). This graph also shows the selectivity thresholds, s=1.0; s=1.1, s=1.2 and s=1.3 as guides for the eyes.

FIG. 7 shows that the four examples EV1 to EV4 according to the second aspect of the invention have a gain up to more than 10% on selectivity while maintaining a sufficient light transmission level, about 70%, relative to the counterexample CEV1. The figure also shows that these same four examples EV1 to EV4 make it possible to achieve levels of selectivity and light transmission comparable to the counterexamples CEV2 and CEV3 corresponding to standard laminated glazings comprising a tinted mineral glass.

It should be noted that examples EV3 and EV4 make it possible to achieve levels of selectivity and light transmission equivalent to examples EV1 and EV2 with a smaller thickness for the absorbent layer based on tungsten oxide. This is a synergistic effect between said absorbent layer based on tungsten oxide and the use of a second tinted substrate.

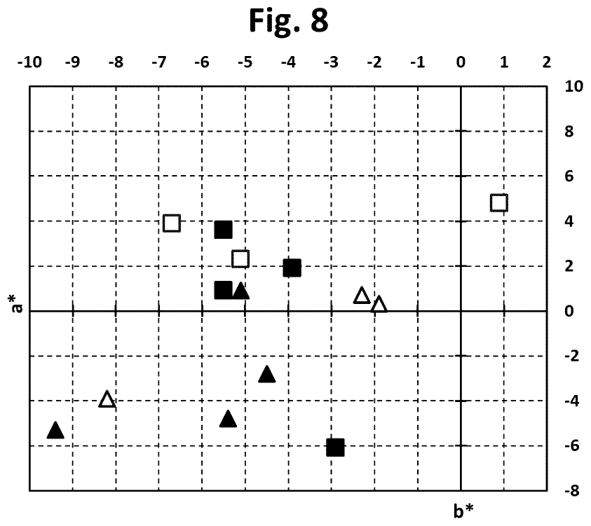

The values of the color parameters a*, b* are shown in FIG. 8 for examples EV1 to EV4 (shown solid) and counterexamples CEV1 to CE 4 (shown empty). The transmission color parameters a*T, b*T are represented by squares and the reflection parameters on the exterior face a*Rext, b*Rext are represented by triangles.

In transmission, examples EV1 to EV4, and more particularly examples EV2 to EV4, have parameters a*T and b*T comparable to those of counterexamples CEV2 and CEV3 of reference laminated glazing. On the contrary, the counterexample CEV1 has parameters a*T and b*T shifted towards the red and yellow.

In reflection, examples EV1 to EV4, and more particularly examples EV2 to EV4, exhibit a*R and b*R parameters comparable to those of counterexamples CEV2 and CEV3 of reference laminated glazing. On the contrary, the counterexample CEV1 has a*R and b*R parameters shifted towards the green and the blue.

These examples very clearly show the advantages of the substrates of the invention, namely that they have a reduced solar factor, a higher selectivity, and have a color compatible with automobile applications.

1. A transparent substrate provided on one of its main surfaces with a stack of thin layers, said stack of layers consisting of the following layers starting from the substrate:
a first dielectric module of one or more thin layers;
an absorbent layer of tungsten oxide;
a second dielectric module of one or more thin layers;
wherein the tungsten oxide comprises at least one doping element selected from the chemical elements of group 1 according to the IUPAC nomenclature,
the absorbent layer of tungsten oxide comprises cesium as a doping element, and a molar ratio of cesium to tungsten is between 0.01 and 1.

2. The substrate according to claim 1, wherein the absorbent layer of tungsten oxide layer comprises the doping element or several doping elements in proportions such that a molar ratio of said element to tungsten or a sum of the molar ratios of each element to tungsten is between 0.01 and 1.

3. The substrate according to claim 1, wherein the absorbent layer of tungsten oxide comprises at least one doping element selected from hydrogen, lithium, sodium, potassium and cesium.

4. The substrate according to claim 1, wherein a thickness of the absorbent layer of tungsten oxide is between 6 and 350 nm.

5. The substrate according to claim 1, wherein the first dielectric module and/or the second dielectric module comprise one or more layers based on nitride and/or oxide.

6. The substrate according to claim 5, wherein a first layer of the first dielectric module and a last layer of the second dielectric mode are nitride-based layers.

7. The substrate according to claim 1, wherein a final layer of the first dielectric module located under and in contact with the absorbent layer based on tungsten oxide and a first layer of the second dielectric module located on and in contact with the absorbent layer based on tungsten oxide are based on nitride.

8. The substrate according to claim 1, wherein the first dielectric module and/or the second dielectric module are composed of nitride-based layers.

9. A laminated glass comprising a first transparent substrate according to claim 1, a lamination interlayer and a second transparent substrate, wherein the first transparent substrate and the second transparent substrates are in adhesive contact with the lamination interlayer and the stack of thin layers of the first transparent substrate is in contact with the lamination interlayer.

10. The laminated glazing according to claim 9, wherein one of the first and second substrates is a glass tinted in the mass.

11. A method for manufacturing a transparent substrate according to claim 1, comprising depositing the absorbent layer of tungsten oxide is by a magnetron sputtering method using a tungsten oxide target doped using a chemical element chosen from the chemical elements of group 1 according to the IUPAC nomenclature.

12. The manufacturing method according to claim 11, wherein the absorbent layer of tungsten oxide is deposited at a substrate temperature of less than 100° C.

13. The manufacturing method according to claim 11, wherein the absorbent layer based on tungsten oxide is deposited in a deposition atmosphere composed of 60 to 100% argon and 0 to 40% dioxygen.

14. The manufacturing method according to claim 11, wherein the absorbent layer of tungsten oxide is deposited at a pressure of between 1 and 15 m Torr.

15. The substrate according to claim 1, wherein the molar ratio of cesium to tungsten is between 0.01 and 0.4.

16. The substrate according to claim 2, wherein the molar ratio of said element to tungsten or the sum of the molar ratios of each element to tungsten is between 0.01 and 0.6.

17. The substrate according to claim 4, wherein the thickness of the absorbent layer of tungsten oxide is between 20 and 250 nm.

18. The substrate according to claim 5, wherein the one or more layers based on nitride and/or oxide are based on zinc and tin oxide, zinc oxide, titanium oxide, zirconium oxide, aluminum nitride, silicon and zirconium nitride or silicon nitride optionally doped with aluminum, zirconium and/or boron.

19. The substrate according to claim 6, wherein the nitride-based layers are layers based on aluminum nitride, silicon and zirconium nitride or silicon nitride optionally doped with aluminum, zirconium and/or boron.

20. The substrate according to claim 7, wherein the final and first layers are based on aluminum nitride, on silicon and zirconium nitride or silicon nitride optionally doped with aluminum, zirconium and/or boron.
